(19) United States
(12) Patent Application Publication
(10) Pub. No.: US 2021/0154797 A1
(43) Pub. Date: May 27, 2021

(54) POLISHING PAD, PREPARATION METHOD THEREOF, AND PREPARATION METHOD OF SEMICONDUCTOR DEVICE USING SAME

(71) Applicant: SKC CO., LTD., Gyeonggi-do (KR)

(72) Inventors: Hyeyoung HEO, Gyeonggi-do (KR); Sunghoon YUN, Gyeonggi-do (KR); Jang Won SEO, Gyeonggi-do (KR); Jong Wook YUN, Gyeonggi-do (KR); Jaein AHN, Gyeonggi-do (KR)

(21) Appl. No.: 17/101,363

(22) Filed: Nov. 23, 2020

(30) Foreign Application Priority Data
Nov. 21, 2019 (KR) 10-2019-0150561

(51) Int. Cl. B24B 37/26; B24B 37/24; H01L 21/02; B24D 18/00

(52) U.S. Cl. CPC B24B 37/26; B24D 18/0009; H01L 21/02013; B24B 37/24

(57) ABSTRACT

Embodiments relate to a polishing pad for use in a chemical mechanical planarization (CMP) process of semiconductors, a process for preparing the same, and a process for preparing a semiconductor device using the same. In the polishing pad according to the embodiments, the number average diameter (Da) and number median diameter (Dm) of a plurality of pores are adjusted to achieve a specific range of the Ed value (Equation 1). As a result, an excellent polishing rate and within-wafer non-uniformity can be achieved.

### TECHNICAL FIELD

Embodiments relate to a polishing pad for use in a chemical mechanical planarization process of semiconductors, a process for preparing the same, and a process for preparing a semiconductor device using the same.

### BACKGROUND ART

The chemical mechanical planarization (CMP) process in a process for preparing semiconductors refers to a step in which a semiconductor substrate such as a wafer is fixed to a head and in contact with the surface of a polishing pad mounted on a platen, and the wafer is then chemically treated by supplying a slurry while the platen and the head are relatively moved, to thereby mechanically planarize the irregularities on the semiconductor substrate.

A polishing pad is an essential member that plays an important role in such a CMP process. In general, a polishing pad is composed of a polyurethane-based resin and has grooves on its surface for a large flow of a slurry and pores for supporting a fine flow thereof.

The pores in a polishing pad may be formed by using a solid phase foaming agent having voids, a liquid phase foaming agent filled with a volatile liquid, an inert gas, a fiber, or the like, or by generating a gas by a chemical reaction.

As the solid phase foaming agent, microcapsules (i.e., thermally expanded microcapsules), whose size has been adjusted by a thermal expansion, are used. Since the thermally expanded microcapsules in a structure of already expanded micro-balloons have a uniform particle diameter, the diameter of pores can be uniformly controlled. However, the thermally expanded microcapsules have a disadvantage in that it is difficult to control the pores to be formed since the shape of the microcapsules changes under the reaction condition of a high temperature of 100° C. or higher.

Korean Laid-open Patent Publication No. 2016-0027075 discloses a process for producing a low-density polishing pad using an inert gas and a pore inducing polymer, and a low-density polishing pad. However, this patent publication has a limitation in the adjustment of the size and distribution of pores and fails to teach the polishing rate of the polishing pad.

Likewise, Korean Patent No. 10-0418648 discloses a process for producing a polishing pad using two kinds of solid phase foaming agents that have different particle diameters. However, this patent also has a limitation in the enhancement of the polishing performance by adjusting the size and distribution of pores.

### PRIOR ART DOCUMENT

### Patent Document

(Patent Document 1) Korean Laid-open Patent Publication No. 2016-0027075

(Patent Document 2) Korean Patent No. 10-0418648

### DETAILED DESCRIPTION OF THE INVENTION

### Technical Problem

Accordingly, an object of the embodiments is to provide a polishing pad whose polishing rate and within-wafer non-uniformity can be enhanced by adjusting the size and distribution of pores, a process for preparing the same, and a process for preparing a semiconductor device using the same.

### Solution to the Problem

In order to achieve the above object, an embodiment provides a polishing pad, which comprises a polishing layer comprising a plurality of pores, wherein the plurality of pores have a number average diameter (Da) of 16 μm to less than 30 μm, and the Ed value represented by the following Equation 1 is greater than 0:

Ed=[3×(Da−Dm)]/STDEV [Equation 1]

In Equation 1, Da stands for the number average diameter of the plurality of pores within 1 mm² of the polishing surface, Dm stands for a number median diameter of the plurality of pores within 1 mm² of the polishing surface, and STDEV stands for a standard deviation of the number average diameter of the plurality of pores within 1 mm of the polishing surface.

Another embodiment provides a process for preparing a polishing pad, which comprises mixing a composition comprising a urethane-based prepolymer, a curing agent, and a solid phase foaming agent; and injecting and mixed the composition into a mold under a reduced pressure to form a polishing layer, wherein the polishing layer comprises a plurality of pores, the plurality of pores have a number average diameter (Da) of 16 μm to less than 30 m, and the Ed value represented by the above Equation 1 is greater than 0.

Another embodiment provides a process for preparing a semiconductor device, which comprises mounting a polishing pad comprising a polishing layer comprising a plurality of pores on a platen; and relatively rotating the polishing pad and a semiconductor substrate while a polishing surface of the polishing layer and a surface of the semiconductor substrate are in contact with each other to polish the surface of the semiconductor substrate, wherein the plurality of pores have a number average diameter (Da) of 16 m to less than 30 μm, and the Ed value represented by the above Equation 1 is greater than 0.

### Advantageous Effects of the Invention

According to the above embodiments, the size and distribution of the plurality of pores contained in a polishing pad are adjusted, whereby the plurality of pores in the polishing pad have specific ranges of the number average diameter (Da) and the Ed value, which can further enhance the polishing rate and within-wafer non-uniformity.

In addition, it is possible to efficiently fabricate a semiconductor device of excellent quality using the polishing pad.

### BRIEF DESCRIPTION OF THE DRAWINGS

FIG. 1 schematically illustrates the process for preparing a semiconductor device according to an embodiment.

### BEST MODE FOR CARRYING OUT THE INVENTION

In the description of the following embodiments, in the case where each layer or pad is mentioned to be formed “on” or “under” another layer or pad, it means not only that one element is “directly” formed on or under another element, but also that one element is “indirectly” formed on or under another element with other element(s) interposed between them.

The term on or under with respect to each element may be referenced to the drawings. For the sake of description, the sizes of individual elements in the appended drawings may be exaggeratingly depicted and do not indicate the actual sizes.

The term “plurality of” as used herein refers to more than one.

In this specification, when a part is referred to as “comprising” an element, it is to be understood that it may comprise other elements as well, rather than excluding the other elements, unless specifically stated otherwise.

In addition, all numerical ranges related to the physical properties, dimensions, and the like of a component used herein are to be understood as being modified by the term “about,” unless otherwise indicated.

Hereinafter, the present invention is explained in detail by the following embodiments. The embodiments can be modified into various forms as long as the gist of the invention is not changed.

Polishing Pad

The polishing pad according to an embodiment comprises a polishing layer comprising a plurality of pores, wherein the plurality of pores have a number average diameter (Da) of 16 μm to less than 30 m, and the Ed value represented by the following Equation 1 is greater than 0.

Ed=[3×(Da−Dm)]/STDEV [Equation 1]

In Equation 1, Da stands for the number average diameter of the plurality of pores within 1 mm² of the polishing surface, Dm stands for a number median diameter of the plurality of pores within 1 mm² of the polishing surface, and STDEV stands for a standard deviation of the number average diameter of the plurality of pores within 1 mm of the polishing surface.

In Equation 1, Ed may be calculated from the number average diameter (Da) of the plurality of pores, the number median diameter of the plurality of pores (Dm), and the standard deviation (STDEV) of the number average diameter of the plurality of pores. In addition, the Da, Dm, and STDEV each may be calculated by measuring the pore diameters of the respective pores observed using a scanning electron microscope (SEM) and an image analysis software on the basis of 1 mm² of the polishing surface.

In the polishing pad according to an embodiment, the flowability of a polishing slurry and the polishing efficiency hinge on the diameters of the pores exposed on the surface thereof. That is, the flowability of a polishing slurry is affected by the diameters of the pores exposed on the surface of the polishing pad, and the occurrence of scratches on the surface of the object to be polished and the polishing rate may be determined by the distribution of pore diameters. In the polishing pad according to an embodiment, the number average diameter and the number median diameter of the plurality of pores are controlled, thereby achieving a specific range of the Ed value, which allows an appropriate design of the surface structure. As a result, an excellent polishing rate and within-wafer non-uniformity can be achieved.

The Ed value represented by Equation 1 has a positive number exceeding 0. Specifically, it may be greater than 0 to less than 2, greater than 0 to less than 1.5, greater than 0 to less than 1.2, greater than 0 to less than 1.0, greater than 0 to less than 0.8, greater than 0 to less than 0.7, greater than 0.1 to less than 0.6, 0.6 to 1.8, or 0.6 to 1.5.

If the Ed value is a positive number, it may mean that Da is greater than Dm. If Da is greater than Dm, the polishing layer contains a large number of relatively small pores, through which the flowability of a slurry and the capability of containing it on the polishing surface of the polishing layer are secured at an appropriate level. Thus, the polishing rate and within-wafer non-uniformity of the polishing pad may be achieved at an appropriate level. If the Ed value is not a positive number, that is, if Da is smaller than Dm, so that it has a negative number, the pore structure exposed on the polishing surface may excessively increase or decrease the flowability of a slurry. Thus, it may be difficult to achieve a desired level of polishing performance such as polishing rate and within-wafer non-uniformity.

The Da in Equation 1 is a number average diameter of a plurality of pores, which may be defined as an average value obtained by dividing the sum of the diameters of the plurality of pores by the number of pores.

According to an embodiment, the Da may be 16 μm to less than 30 μm, 16 μm to 26 μm, 19.8 μm to 26 μm, 20 μm to 25 μm, or 20 μm to 23 μm.

If the polishing pad according to an embodiment of the present invention has a Da within the above range, the polishing rate and within-wafer non-uniformity can be enhanced. If the Da is less than 16 μm, the polishing rate for an oxide layer may be excessively increased, or the polishing rate for a tungsten layer may be excessively decreased, and the within-wafer non-uniformity may be deteriorated. On the other hand, if the Da is 30 μm or more, the polishing rate for a tungsten layer may be excessively increased, and the within-wafer non-uniformity for a tungsten layer may be deteriorated.

In addition, the Dm in Equation 1 is a number median diameter of a plurality of pores, which may be defined as a median value of a diameter at the center when the entire diameters of a plurality of pores are arranged in order of size. That is, the median value refers to a value located at the center of the plurality of pore diameters, or a value less than that occupies half of the total pore diameter values.

According to an embodiment, the Dm may be 12 μm to 28 μm, 13 μm to 26 μm, 15 μm to 25 μm, 17 μm to 25 μm, 17 μm to 23 μm, 19 μm to 26 μm, 19 μm to 23 μm, or 15 μm to 20 μm.

If the polishing pad according to an embodiment of the present invention has a Dm within the above range, the polishing rate and within-wafer non-uniformity can be enhanced. If the Dm is outside the above range, the polishing rate for a tungsten layer or an oxide layer may be excessively decreased, or the within-wafer non-uniformity may be deteriorated.

In addition, in order to for the Ed to have a positive number, Da must have a value greater than Dm. Specifically, Da may be greater than Dm by 0.3 μm to 3 μm, 0.4 μm to less than 2.5 μm, 0.4 μm to 2.3 μm, 0.5 μm to 2 μm, 0.7 μm to 2 μm, 0.8 μm to 1.9 μm, 0.5 μm to 1 μm, or 1.1 μm to 2 μm.

Meanwhile, the STDEV in Equation 1 may be defined as the standard deviation of the number average diameter of the plurality of pores.

According to an embodiment, the STDEV may be 5 to 15, 6 to 13, 6 to 12, 8 to 15, 7 to 12, 8 to 14, or 8 to 11.

If the polishing pad according to an embodiment of the present invention has an STDEV within the above range, the polishing rate and within-wafer non-uniformity can be enhanced. If the STDEV is less than 5, there may be a problem that the polishing within-wafer non-uniformity for a tungsten layer or an oxide layer is excessively deteriorated or the physical properties of the polishing pad are deteriorated. If it exceeds 15, there may be a problem that the polishing rate for a tungsten layer or an oxide layer is excessively increased and the polishing within-wafer non-uniformity is also deteriorated.

According to an embodiment, when the Da is 16 μm to less than 21 μm, the Ed value may be greater than 0.5 to less than 2; and when the Da is 21 μm to less than 30 μm, the Ed value may be 0.1 to 0.5.

The polishing pad may contain pores in an area ratio of 30% to 70%, or 30% to 60%, based on 100% of the total cross-sectional area of the polishing pad.

According to the above embodiment, the size and distribution of the plurality of pores contained in the polishing pad are adjusted, whereby it has specific ranges of such parameters as Ed, Da, and Dm, which can further enhance the polishing rate and within-wafer non-uniformity. Specifically, the polishing pad may have a polishing rate for a tungsten layer of 700 Å/min to 900 Å/min, 760 Å/min to 900 Å/min, 760 Å/min to 800 Å/min, or 700 Å/min to 795 Å/min.

In addition, the polishing pad have a polishing rate for an oxide layer of 2,750 Å/min to 3,200 Å/min, 2,750 Å/min to 3,100 Å/min, 2,850 Å/min to 3,200 Å/min, 2,800 Å/min to 3,100 Å/min, or 2,890 Å/min to 3,100 Å/min. Further, with regard to the within-wafer non-uniformity (WIWNU), which indicates the polishing uniformity in the surface of a semiconductor substrate, the within-wafer non-uniformity for a tungsten layer may be less than 10%, less than 9%, 4.5% or less, or less than 4.3%. In addition, the within-wafer non-uniformity for an oxide layer may be less than 12%, less than 10%, less than 9%, less than 8%, less than 6%, less than 5%, or less than 4%.

Meanwhile, the polishing pad is composed of a polyurethane resin, and the polyurethane resin may be derived from a urethane-based prepolymer having an isocyanate terminal group. In such event, the polyurethane resin comprises monomer units that constitute the prepolymer.

A prepolymer generally refers to a polymer having a relatively low molecular weight wherein the degree of polymerization is adjusted to an intermediate level for the sake of conveniently molding a product in the process of producing the same. A prepolymer may be molded by itself or after a reaction with another polymerizable compound. For example, a prepolymer may be prepared by reacting an isocyanate compound with a polyol.

For example, the isocyanate compound that may be used in the preparation of the urethane-based prepolymer may be at least one isocyanate selected from the group consisting of toluene diisocyanate (TDI), naphthalene-1,5-diisocyanate, p-phenylene diisocyanate, tolidine diisocyanate, 4,4′-diphenyl methane diisocyanate, hexamethylene diisocyanate, dicyclohexylmethane diisocyanate, and isophorone diisocyanate.

For example, the polyol that may be used in the preparation of the urethane-based prepolymer may be at least one polyol selected from the group consisting of a polyether polyol, a polyester polyol, a polycarbonate polyol, and an acryl polyol. The polyol may have a weight average molecular weight (Mw) of 300 g/mole to 3,000 g/mole.

Process for Preparing a Polishing Pad

The process for preparing a polishing pad according to an embodiment comprises mixing a composition comprising a urethane-based prepolymer, a curing agent, and a solid phase foaming agent; and injecting the mixed composition into a mold under a reduced pressure to form a polishing layer, wherein the polishing layer comprises a plurality of pores, the plurality of pores have a number average diameter (Da) of 16 μm to less than 30 m, and the Ed value represented by the above Equation 1 is greater than 0.

Specifically, the process for preparing a polishing pad according to an embodiment may comprise mixing a composition comprising a urethane-based prepolymer, a curing agent, and a solid phase foaming agent (step 1).

Step 1 is a step of mixing the respective components, through which it is possible to obtain a mixture of a urethane-based prepolymer, a solid phase foaming agent, and a curing agent. The curing agent may be added together with the urethane-based prepolymer and the solid phase foaming agent, or the urethane-based prepolymer and the solid phase foaming agent may be mixed first, followed by second mixing of the curing agent.

As an example, the urethane-based prepolymer, the solid phase foaming agent, and the curing agent may be put into the mixing step substantially at the same time.

As another example, the urethane-based prepolymer and the solid phase foaming agent may be mixed in advance, and the curing agent may be subsequently introduced. That is, the curing agent may not be mixed in advance with the urethane-based prepolymer. If the curing agent is mixed in advance with the urethane-based prepolymer, it may be difficult to control the reaction rate. In particular, the stability of the prepolymer having an isocyanate terminal group may be significantly impaired.

The step of preparing the mixture is a step for initiating the reaction of the urethane-based prepolymer and the curing agent by mixing them and uniformly dispersing the solid phase foaming agent. Specifically, the mixing may be carried out at a speed of 1,000 rpm to 10,000 rpm or 4,000 rpm to 7,000 rpm. Within the above speed range, it may be more advantageous for the solid phase foaming agent to be uniformly dispersed in the raw materials.

In addition, a gas phase foaming agent may be added during the mixing to form a plurality of pores.

In addition, the composition may further comprise a reaction rate controlling agent and/or a curing agent.

According to an embodiment of the present invention, a solid phase foaming agent, a gas phase foaming agent, or both may be employed, and their contents, the average particle diameter of the solid phase foaming agent, and the standard deviation of the particle diameter of the solid phase foaming agent are adjusted, thereby adjusting the number average diameter and number median diameter of the plurality of pores, resulting in a polishing pad having a specific range of the Ed value. As a result, an excellent polishing rate and within-wafer non-uniformity can be achieved.

Hereinafter, the specific components employed in the polishing pad and the process conditions will be described in detail.

Urethane-Based Prepolymer

The urethane-based prepolymer may be prepared by reacting an isocyanate compound with a polyol as described above. The specific types of the isocyanate compound and the polyol are as exemplified above with respect to the polishing pad.

The urethane-based prepolymer may have a weight average molecular weight of 500 g/mole to 3,000 g/mole. Specifically, the urethane-based prepolymer may have a weight average molecular weight (Mw) of 600 g/mole to 2,000 g/mole or 800 g/mole to 1,000 g/mole.

As an example, the urethane-based prepolymer may be a polymer having a weight average molecular weight (Mw) of 500 g/mole to 3,000 g/mole, which is polymerized from toluene diisocyanate as an isocyanate compound and polytetramethylene ether glycol as a polyol.

Curing Agent

The curing agent may be at least one of an amine compound and an alcohol compound. Specifically, the curing agent may comprise at least one compound selected from the group consisting of an aromatic amine, an aliphatic amine, an aromatic alcohol, and an aliphatic alcohol.

For example, the curing agent may be at least one selected from the group consisting of 4,4′-methylenebis(2-chloroaniline) (MOCA), diethyltoluenediamine, diaminodiphenylmethane, diaminodiphenyl sulphone, m-xylylenediamine, isophoronediamine, ethylenediamine, diethylenetriamine, triethylenetetramine, polypropylenediamine, polypropylenetriamine, ethylene glycol, diethylene glycol, dipropylene glycol, butanediol, hexanediol, glycerin, trimethylolpropane, and bis(4-amino-3-chlorophenyl)methane.

Solid Phase Foaming Agent

According to an embodiment of the present invention, the solid phase foaming agent may be a very important factor in controlling the number average diameter and number median diameter of a plurality of pores and achieving the Ed value of the present invention. That is, the average particle diameter (D50), the standard deviation thereof, and the introduced amount of the solid phase foaming agent are controlled to adjust the Ed value represented by Equation 1 to be greater than 0 and the number average diameter (Da) of a plurality of pores to be 16 μm to less than 30 μm.

The solid phase foaming agent is thermally expanded (i.e., size-controlled) microcapsules and may be in a structure of micro-balloons having an average pore size of 5 μm to 200 μm. The thermally expanded (i.e., size-controlled) microcapsules may be obtained by thermally expanding thermally expandable microcapsules.

The thermally expandable microcapsule may comprise a shell comprising a thermoplastic resin; and a foaming agent encapsulated inside the shell. The thermoplastic resin may be at least one selected from the group consisting of a vinylidene chloride-based copolymer, an acrylonitrile-based copolymer, a methacrylonitrile-based copolymer, and an acrylic-based copolymer. Further, the foaming agent encapsulated in the inside may be at least one selected from the group consisting of hydrocarbons having 1 to 7 carbon atoms. Specifically, the foaming agent encapsulated in the inside may be selected from the group consisting of a low molecular weight hydrocarbon such as ethane, ethylene, propane, propene, n-butane, isobutane, butene, isobutene, n-pentane, isopentane, neopentane, n-hexane, heptane, petroleum ether, and the like; a chlorofluorohydrocarbon such as trichlorofluoromethane (CC₃F), dichlorodifluoromethane (CCl₂F₂), chlorotrifluoromethane (CClF₃), tetrafluoroethylene (CCIF₂—CCIF₂), and the like; and a tetraalkylsilane such as tetramethylsilane, trimethylethylsilane, trimethylisopropylsilane, trimethyl-n-propylsilane, and the like.

The solid phase foaming agent may have an average diameter (D50) of 16 μm to 50 μm. Here, the term D50 may refer to the volume fraction of the 50^{th} percentile (median) of a particle diameter distribution. More specifically, the solid phase foaming agent may have a D50 of 16 μm to 48 μm. Even more specifically, the solid phase foaming agent may have a D50 of 18 μm to 48 m; 18 μm to 45 μm; 18 μm to 40 μm; 28 μm to 40 μm; 18 μm to less than 34 μm, or 30 μm to 40 μm. If the D50 of the solid phase foaming agent satisfies the above range, the polishing rate and within-wafer non-uniformity can be further enhanced. If the D50 of the solid phase foaming agent is less than the above range, the number average diameter of pores may be decreased, which may have an adverse impact on the polishing rate and within-wafer non-uniformity. If it exceeds the above range, the number average diameter of pores is excessively increased, which may have an adverse impact on the polishing rate and within-wafer non-uniformity.

In addition, the standard deviation of the average particle diameter of the solid phase foaming agent may be 12 or less, 11 or less, 10 or less, 9.9 or less, 5 to 12, 5 to 11, 5 to 10, or 5 to 9.9.

The solid phase foaming agent may be employed in an amount of 0.7 parts by weight to 2 parts by weight based on 100 parts by weight of the composition for a polishing pad. Specifically, the solid phase foaming agent may be employed in an amount of 0.8 parts by weight to 1.2 parts by weight, 1 part by weight to 1.5 parts by weight, 1 part by weight to 1.25 parts by weight, or 1.3 parts by weight to 1.5 parts by weight, based on 100 parts by weight of the composition for a polishing pad. If the content of the solid phase foaming agent exceeds the above range, there may be a problem that the number average diameter of the pores is excessively decreased. If the content of the solid foaming agent is less than the above range, there may be a problem that the number average diameter of the pores is excessively increased, or the number average diameter Da of the pores may be smaller than the number median diameter Dm of the pores, resulting in a negative Ed value.

In addition, the solid phase foaming agent may be a fine hollow particle having a shell. The glass transition temperature (Tg) of the shell may be 70° C. to 110° C., 80° C. to 110° C., 90° C. to 110° C., 100° C. to 110° C., 70° C. to 100° C., 70° C. to 90° C., or 80° C. to 100° C. If the glass transition temperature of the shell of the solid phase foaming agent is within the preferable range, the size and distribution of pores in the polishing layer may be achieved within the above desired range.

Reaction Rate Controlling Agent

The reaction rate controlling agent may be a reaction promoter or a reaction retarder. Specifically, the reaction rate controlling agent may be a reaction promoter. For example, it may be at least one reaction promoter selected from the group consisting of a tertiary amine-based compound and an organometallic compound.

Specifically, the reaction rate controlling agent may comprise at least one selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may comprise at least one selected from the group consisting of benzyldimethylamine, N,N-dimethylcyclohexylamine, and triethylamine.

According to an embodiment of the present invention, the reaction rate controlling agent may be a very important factor in controlling the number average diameter and number median diameter of a plurality of pores and achieving the Ed value of the present invention. In particular, the content of the reaction rate controlling agent is controlled to adjust the Ed value represented by Equation 1 to be greater than 0 and the number average diameter (Da) of a plurality of pores to be 16 μm to less than 30 μm.

Specifically, the reaction rate controlling agent may be employed in an amount of 0.05 parts by weight to 2 parts by weight based on 100 parts by weight of the composition for a polishing pad. Specifically, the reaction rate controlling agent may be employed in an amount of 0.05 parts by weight to 1.8 parts by weight, 0.05 parts by weight to 1.7 parts by weight, 0.05 parts by weight to 1.6 parts by weight, 0.1 parts by weight to 1.5 parts by weight, 0.1 parts by weight to 0.6 parts by weight, 0.2 parts by weight to 1.8 parts by weight, 0.2 parts by weight to 1.7 parts by weight, 0.2 parts by weight to 1.5 parts by weight, 0.2 parts by weight to 1 part by weight, 0.3 parts by weight to 0.6 parts by weight, 0.1 parts by weight to 0.5 parts by weight, or 0.5 parts by weight to 1 part by weight, based on 100 parts by weight of the composition for a polishing pad. If the reaction rate controlling agent is employed in an amount within the above range, the reaction rate (i.e., the time for solidification) of the mixture (i.e., the urethane-based prepolymer, the curing agent, the solid phase foaming agent, the reaction rate controlling agent, and the silicone-based surfactant) is properly controlled, so that it is possible to achieve the size and distribution of pores desired in the present invention. If the reaction rate controlling agent is not employed or the content thereof is outside the above range, the number average diameter Da of the pores may be smaller than the number median diameter Dm of the pores, resulting in a negative Ed value.

Surfactant

The surfactant may comprise a silicone-based surfactant. It may act to prevent the pores to be formed from overlapping and coalescing with each other. The kind of the surfactant is not particularly limited as long as it is commonly used in the production of a polishing pad.

Examples of the commercially available silicone-based surfactant include B8749LF, B8736LF2, and B8734LF2 manufactured by Evonik.

The silicone-based surfactant may be employed in an amount of 0.2 parts by weight to 2 parts by weight based on 100 parts by weight of the composition for a polishing pad. Specifically, the silicone-based surfactant may be employed in an amount of 0.2 parts by weight to 1.9 parts by weight, 0.2 parts by weight to 1.8 parts by weight, 0.2 parts by weight to 1.7 parts by weight, 0.2 parts by weight to 1.6 parts by weight, 0.2 parts by weight to 1.5 parts, or 0.5 parts by weight to 1.5 parts by weight, based on 100 parts by weight of the composition for a polishing pad. If the silicone-based surfactant is employed in an amount within the above range, the pores to be derived from the gas phase foaming agent can be stably formed and maintained in the mold.

Gas Phase Foaming Agent

The gas phase foaming agent may comprise an inert gas. The gas phase foaming agent is fed when the urethane-based prepolymer, the curing agent, the solid phase foaming agent, the reaction rate controlling agent, and the silicone-based surfactant are mixed and reacted, to thereby form pores. The kind of the inert gas is not particularly limited as long as it is a gas that does not participate in the reaction between the prepolymer and the curing agent. For example, the inert gas may be at least one selected from the group consisting of nitrogen gas (N₂), argon gas (Ar), and helium gas (He). Specifically, the inert gas may be nitrogen gas (N₂) or argon gas (Ar).

According to an embodiment of the present invention, the gas phase foaming agent may be a very important factor in controlling the number average diameter and median diameter of a plurality of pores and achieving the Ed value of the present invention. In particular, the content of the gas phase foaming agent is controlled to adjust the Ed value represented by Equation 1 to be greater than 0 and the number average diameter (Da) of a plurality of pores to be 16 μm to less than 30 μm.

The gas phase foaming agent may be introduced in a volume of 6% to less than 25% based on the total volume of the composition for a polishing pad. Specifically, the inert gas may be introduced in a volume of 6% to 20%, 8% to 20%, 10% to 15%, 13% to 20%, or 15% to 20%. If the content of the inert gas exceeds the above range, the number average diameter Da of the pores may be smaller than the number median diameter Dm of the pores, resulting in a negative Ed value.

As another example, the urethane-based prepolymer, the curing agent, the solid phase foaming agent, the reaction rate controlling agent, the silicone-based surfactant, and the inert gas may be put into the mixing process substantially at the same time.

As another example, the urethane-based prepolymer, the solid phase foaming agent, and the silicone-based surfactant may be mixed in advance, and the curing agent, the reaction rate controlling agent, and the inert gas may be subsequently introduced. That is, the reaction rate controlling agent is not mixed in advance with the urethane-based prepolymer or the curing agent.

If the reaction rate controlling agent is mixed in advance with the urethane-based prepolymer, curing agent, or the like, it may be difficult to control the reaction rate. In particular, the stability of the prepolymer having an isocyanate terminal group may be significantly impaired.

The mixing initiates the reaction of the urethane-based prepolymer and the curing agent by mixing them and uniformly disperses the solid phase foaming agent and the inert gas in the raw materials. In such event, the reaction rate controlling agent may intervene in the reaction between the urethane-based prepolymer and the curing agent from the beginning of the reaction, to thereby control the reaction rate. Specifically, the mixing may be carried out at a speed of 1,000 rpm to 10,000 rpm or 4,000 rpm to 7,000 rpm. Within the above speed range, it may be more advantageous for the inert gas and the solid phase foaming agent to be uniformly dispersed in the raw materials.

The urethane-based prepolymer and the curing agent may be mixed at a molar equivalent ratio of 1:0.8 to 1:1.2, or a molar equivalent ratio of 1:0.9 to 1:1.1, based on the number of moles of the reactive groups in each molecule. Here, “the number of moles of the reactive groups in each molecule” refers to, for example, the number of moles of the isocyanate group in the urethane-based prepolymer and the number of moles of the reactive groups (e.g., amine group, alcohol group, and the like) in the curing agent. Therefore, the urethane-based prepolymer and the curing agent may be fed at a constant rate during the mixing process by controlling the feeding rate such that the urethane-based prepolymer and the curing agent are fed in amounts per unit time that satisfies the molar equivalent ratio exemplified above.

Reaction and Formation of Pores

The urethane-based prepolymer and the curing agent react with each other upon the mixing thereof to form a solid polyurethane, which is then formed into a sheet or the like. Specifically, the isocyanate terminal group in the urethane-based prepolymer can react with the amine group, the alcohol group, and the like in the curing agent. In such event, the gas phase foaming agent comprising an inert gas and the solid phase foaming agent are uniformly dispersed in the raw materials to form pores without participating in the reaction between the urethane-based prepolymer and the curing agent.

In addition, the reaction rate controlling agent adjusts the diameter of the pores by promoting or retarding the reaction between the urethane-based prepolymer and the curing agent. For example, if the reaction rate controlling agent is a reaction retarder for delaying the reaction, the time for which the inert gas finely dispersed in the raw materials are combined with each other is prolonged, so that the average diameter of the pores can be increased. On the other hand, if the reaction rate controlling agent is a reaction promoter for expediting the reaction, the time for which the inert gas finely dispersed in the raw materials are combined with each other is shortened, so that the average diameter of the pores can be reduced.

Molding

The molding is carried out using a mold. Specifically, the raw materials (i.e., the urethane-based prepolymer, the curing agent, the solid phase foaming agent, the reaction rate controlling agent, the silicone-based surfactant, and the inert gas) sufficiently stirred in a mixing head or the like may be injected into a mold to fill the inside thereof. The reaction between the urethane-based prepolymer and the curing agent is completed in the mold to thereby produce a molded body in the form of a solidified cake that conforms to the shape of the mold.

Thereafter, the molded body thus obtained may be appropriately sliced or cut into a polishing layer for the production of a polishing pad. As an example, a molded body is produced in a mold having a height of 5 to 50 times the thickness of a polishing pad to be finally produced and is then sliced in the same thickness to produce a plurality of sheets for the polishing pads at a time. In such event, a reaction retarder may be used as a reaction rate controlling agent in order to secure a sufficient solidification time. Thus, the height of the mold may be about 5 to about 50 times the thickness of the polishing pad to be finally produced to prepare sheets therefor. However, the polishing layer or sliced sheets may have pores of different diameters depending on the molded location inside the mold. That is, a polishing layer molded at the lower position of the mold has pores of a fine diameter, whereas a polishing layer molded at the upper position of the mold may have pores of a larger diameter than that of the polishing layer formed at the lower position.

Therefore, it is preferable to use a mold capable of producing one sheet by one molding in order for each sheet to have pores of a uniform diameter. To this end, the height of the mold may not significantly differ from the thickness of the polishing pad to be finally produced. For example, the molding may be carried out using a mold having a height of 1 to 3 times the thickness of the polishing pad to be finally produced. More specifically, the mold may have a height of 1.1 to 2.5 times, or 1.2 to 2 times, the thickness of the polishing pad to be finally produced. In such event, a reaction promoter may be used as the reaction rate controlling agent to form pores having a more uniform diameter.

Thereafter, the top and bottom ends of the molded body obtained from the mold may be cut out, respectively. For example, each of the top and bottom ends of the molded body may be cut out by ⅓ or less, 1/22 to 3/10, or 1/12 to ¼ of the total thickness of the molded body.

As a specific example, the molding is carried out using a mold having a height of 1.2 to 2 times the thickness of the polishing pad to be finally produced, and a further step of cutting out each of the top and bottom ends of the molded body obtained from the mold upon the molding by 1/12 to ¼ of the total thickness of the molded body may then be carried out.

Subsequent to the above cutting step, the above preparation process may further comprise the steps of machining grooves on the surface of the molded body, bonding with the lower part, inspection, packaging, and the like. These steps may be carried out in a conventional manner for preparing a polishing pad.

Physical Properties of the Polishing Pad

As described above, if the Ed value and Da are within the above ranges, the polishing performance such as polishing rate and within-wafer non-uniformity can be remarkably enhanced.

The polishing pad may have a total number of pores of 600 or more per unit area (mm²) of the polishing pad. More specifically, the total number of pores may be 700 or more per unit area (mm²) of the polishing pad. Even more specifically, the total number of pores may be 800 or more per unit area (mm²) of the polishing pad. Even more specifically, the total number of pores may be 900 or more per unit area (mm²) of the polishing pad. But it is not limited thereto. In addition, the total number of pores may be 1,500 or less, specifically 1,200 or less, per unit area (mm²) of the polishing pad. But it is not limited thereto. Thus, the total number of pores may be 800 to 1,500, for example, 800 to 1,200, per unit area (mm²) of the polishing pad. But it is not limited thereto.

Specifically, the polishing pad may have an elastic modulus of 60 kgf/cm² or more. More specifically, the polishing pad may have an elastic modulus of 100 kgf/cm or more, but it is not limited thereto. The upper limit of the elastic modulus of the polishing pad may be 150 kgf/cm², but it is not limited thereto.

In addition, the polishing pad according to an embodiment may be excellent in polishing performance, as well as basic physical properties of a polishing pad such as breakdown voltage, specific gravity, surface hardness, tensile strength, and elongation.

The physical properties of the polishing pad such as specific gravity and hardness can be controlled through the molecular structure of the urethane-based prepolymer polymerized by the reaction between an isocyanate and a polyol.

Specifically, the polishing pad may have a hardness of 30 Shore D to 80 Shore D. More specifically, the polishing pad may have a hardness of 40 Shore D to 70 Shore D, but it is not limited thereto.

Specifically, the polishing pad may have a specific gravity of 0.6 g/cm³ to 0.9 g/cm³. More specifically, the polishing pad may have a specific gravity of 0.7 g/cm³ to 0.85 g/cm³, but it is not limited thereto.

Specifically, the polishing pad may have a tensile strength of 10 N/mm² to 100 N/mm². More specifically, the polishing pad may have a tensile strength of 15 N/mm² to 70 N/mm². Even more specifically, the polishing pad may have a tensile strength of 20 N/mm² to 70 N/mm², but it is not limited thereto.

Specifically, the polishing pad may have an elongation of 30% to 300%. More specifically, the polishing pad may have an elongation of 50% to 200%.

The polishing pad may have a breakdown voltage of 14 kV to 23 kV, a thickness of 1.5 mm to 2.5 mm, a specific gravity of 0.7 g/cm³ to 0.9 g/cm³, a surface hardness at 25° C. of 50 shore D to 65 shore D, a tensile strength of 15 N/mm² to 25 N/mm², and an elongation of 80% to 250%, but t is not limited thereto.

The polishing pad may have a thickness of 1 mm to 5 mm. Specifically, the polishing pad may have a thickness of 1 mm to 3 mm, 1 mm to 2.5 mm, 1.5 mm to 5 mm, 1.5 mm to 3 mm, 1.5 mm to 2.5 mm, 1.8 mm to 5 mm, 1.8 mm to 3 mm, or 1.8 mm to 2.5 mm. If the thickness of the polishing pad is within the above range, the basic physical properties as a polishing pad can be sufficiently exhibited.

The polishing pad may have grooves on its surface for mechanical polishing. The grooves may have a depth, a width, and a spacing as desired for mechanical polishing, which are not particularly limited.

The polishing pad according to an embodiment may simultaneously have the physical properties of the polishing pad as described above.

[Process for Preparing a Semiconductor Device]

The process for preparing a semiconductor device according to an embodiment comprises polishing the surface of a semiconductor substrate using the polishing pad according to an embodiment.

That is, the process for preparing a semiconductor device according to an embodiment comprises mounting a polishing pad comprising a polishing layer comprising a plurality of pores on a platen; and relatively rotating the polishing pad and a semiconductor substrate while a polishing surface of the polishing layer and a surface of the semiconductor substrate are in contact with each other to polish the surface of the semiconductor substrate, wherein the plurality of pores have a number average diameter (Da) of 16 μm to less than 30 μm, and the Ed value represented by the above Equation 1 is greater than 0.

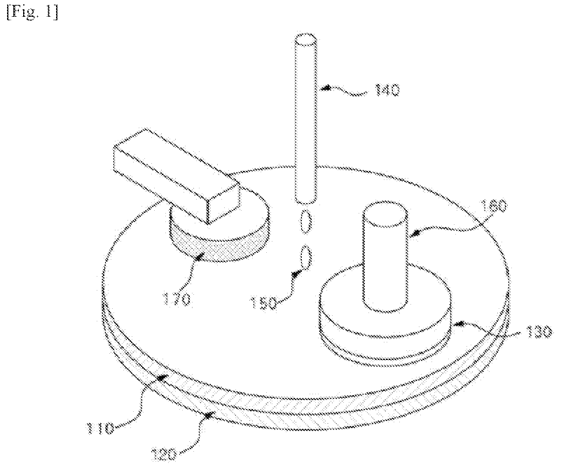

FIG. 1 schematically illustrates the process for preparing a semiconductor device according to an embodiment. Referring to FIG. 1, once the polishing pad (110) according to an embodiment is attached to a platen (120), a semiconductor substrate (130) is disposed on the polishing pad (110). In such event, the surface of the semiconductor substrate (130) is in direct contact with the polishing surface of the polishing pad (110). A polishing slurry (150) may be sprayed through a nozzle (140) on the polishing pad for polishing. The flow rate of the polishing slurry (150) supplied through the nozzle (140) may be selected according to the purpose within a range of about 10 cm³/min to about 1,000 cm³/min. For example, it may be about 50 cm³/min to about 500 cm³/min, but it is not limited thereto.

Thereafter, the semiconductor substrate (130) and the polishing pad (110) rotate relatively to each other, so that the surface of the semiconductor substrate (130) is polished. In such event, the rotation direction of the semiconductor substrate (130) and the rotation direction of the polishing pad (110) may be the same direction or opposite directions. The rotation speeds of the semiconductor substrate (130) and the polishing pad (110) may be selected according to the purpose within a range of about 10 rpm to about 500 rpm. For example, it may be about 30 rpm to about 200 rpm, but it is not limited thereto.

The semiconductor substrate (130) mounted on the polishing head (160) is pressed against the polishing surface of the polishing pad (110) at a predetermined load to be in contact therewith, the surface thereof may then be polished. The load applied to the polishing surface of the polishing pad (110) through the surface of the semiconductor substrate (130) by the polishing head (160) may be selected according to the purpose within a range of about 1 gf/cm² to about 1,000 gf/cm². For example, it may be about 10 gfcm² to about 800 gfcm², but it is not limited thereto.

In an embodiment, in order to maintain the polishing surface of the polishing pad (110) in a state suitable for polishing, the process for preparing a semiconductor device may further comprise processing the polishing surface of the polishing pad (110) with a conditioner (170) simultaneously with polishing the semiconductor substrate (130).

According to the embodiments of the present invention, the number average diameter (Da) and number median diameter (Dm) of a plurality of pores are adjusted to achieve a specific range of the Ed value (Equation 1), whereby an excellent polishing rate and within-wafer non-uniformity can be achieved. Thus, it is possible to efficiently fabricate a semiconductor device of excellent quality using the polishing pad.

### EMBODIMENTS FOR CARRYING OUT THE INVENTION

### Example

Hereinafter, the present invention is explained in detail by the following Examples. However, these examples are set forth to illustrate the present invention, and the scope of the present invention is not limited thereto.

### Example 1: Preparation of a Polishing Pad

1-1: Configuration of the Device

In a casting machine equipped with feeding lines for a urethane-based prepolymer, a curing agent, an inert gas, and a reaction rate controlling agent, PUGL-550D (SKC) having an unreacted NCO content of 9.1% by weight was charged to the prepolymer tank, and bis(4-amino-3-chlorophenyl)methane (Ishihara) was charged to the curing agent tank. Nitrogen (N₂) as an inert gas and a reaction promoter (a tertiary amine compound; manufacturer: Air Products, product name: A1) as a reaction rate controlling agent were provided to prepare a composition for a polishing pad. In addition, 1.5 parts by weight of a solid phase foaming agent (manufacturer: AkzoNobel, product name: Expancel 461 DET 20 d40, average particle diameter: 33.8 μm) and 1 part by weight of a silicone surfactant (manufacturer: Evonik, product name: B8462) were mixed in advance based on 100 parts by weight of the composition for a polishing pad and then charged into the prepolymer tank.

1-2: Preparation of a Polishing Pad

The urethane-based prepolymer, the curing agent, the solid phase foaming agent, the reaction rate controlling agent, and the inert gas were stirred while they were fed to the mixing head at constant speeds through the respective feeding lines. In such event, the molar equivalent ratio of the NCO group in the urethane-based prepolymer to the reactive groups in the curing agent was adjusted to 1:1, and the total feeding amount was maintained at a rate of 10 kg/min. In addition, the inert gas was constantly fed in a volume of 10% based on the total volume of the composition for a polishing pad. The reaction rate controlling agent was fed in an amount of 0.5 parts by weight based on 100 parts by weight of the composition for a polishing pad.

The mixed raw materials were injected into a mold (having a width of 1,000 mm, a length of 1,000 mm, and a height of 3 mm) and solidified to obtain a sheet. Thereafter, the surface of the porous polyurethane layer was ground using a grinder and then grooved using a tip, so that the porous polyurethane had an average thickness of 2 mm.

The porous polyurethane and a substrate layer (average thickness: 1.1 mm) were thermally bonded at 120° C. with a hot-melt film (manufacturer: SKC, product name: TF-00) to produce a polishing pad.

### Examples 2 to 4

A polishing pad was prepared in the same manner as in Example 1, except that the average particle diameter of the solid phase foaming agent, the standard deviation of the average particle diameter of the solid phase foaming agent, and the introduced amounts of the reaction rate control agent, inert gas, and solid phase foaming agent were adjusted to control the number average diameter of pores and the Ed value represented by Equation 1 as shown in Table 1 below.

### Comparative Examples 1 to 4

A polishing pad was prepared in the same manner as in Example 1, except that the average particle diameter of the solid phase foaming agent, the standard deviation of the average particle diameter of the solid phase foaming agent, and the introduced amounts of the reaction rate control agent, inert gas, and solid phase foaming agent were adjusted to control the number average diameter of pores and the Ed value represented by Equation 1 as shown in Table 1 below.

### Test Example

The properties of the polishing pads produced in Examples 1 to 4 were measured according to the following conditions and procedures. The results are shown in Table 1 below.

(1) Number Average Diameter of a Plurality of Ores (Da)

The polishing pad was cut into a square of 1 mm×1 mm, and the cross-section of the polishing surface of 1 mm² was observed with a scanning electron microscope (SEM) from the image magnified 100 times.
Number average diameter (Da): an average value obtained by dividing the sum of the diameters of the plurality of pores within 1 mm² of the polishing surface by the number of pores
Number median diameter (Dm): a median value of a diameter at the center when the entire diameters of a plurality of pores within 1 mm² of the polishing surface are arranged in order of size.
standard deviation (STDEV): a standard deviation of the number average diameter of a plurality of pores within 1 mm² of the polishing surface.
Ed: calculated according to the following Equation 1 using the Da, Dm, and STDEV:

Ed=[3×(Da−Dm)]/STDEV [Equation 1]

(2) Polishing Rates for a Tungsten Layer and an Oxide Layer

A silicon wafer having a size of 300 mm with a tungsten (W) layer formed by a CVD process was set in a CMP polishing machine. The silicon wafer was set on the polishing pad mounted on the platen, while the tungsten layer of the silicon wafer faced downward. Thereafter, the tungsten layer was polished under a polishing load of 2.8 psi while the platen was rotated at a speed of 115 rpm for 30 seconds and a calcined silica slurry was supplied onto the polishing pad at a rate of 190 ml/min. Upon completion of the polishing, the silicon wafer was detached from the carrier, mounted in a spin dryer, washed with deionized water (DIW), and then dried with air for 15 seconds. The layer thickness of the dried silicon wafer was measured before and after the polishing using a contact type sheet resistance measuring instrument (with a 4-point probe). Then, the polishing rate was calculated with the above Equation 2.

Polishing rate (Å/minute)=difference in thickness before and after polishing (Å)/polishing time (minute) [Equation 2]

In addition, a silicon wafer having a size of 300 mm with a silicon oxide (SiOx) layer formed by a TEOS-plasma CVD process was used, instead of the silicon wafer with a tungsten layer, in the same device. The silicon wafer was set on the polishing pad mounted on the platen, while the silicon oxide layer of the silicon wafer faced downward. Thereafter, the silicon oxide layer was polished under a polishing load of 1.4 psi while the platen was rotated at a speed of 115 rpm for 60 seconds and a calcined silica slurry was supplied onto the polishing pad at a rate of 190 ml/min. Upon completion of the polishing, the silicon wafer was detached from the carrier, mounted in a spin dryer, washed with deionized water (DIW), and then dried with air for 15 seconds. The difference in film thickness of the dried silicon wafer before and after the polishing was measured using a spectral reflectometer type thickness measuring instrument (manufacturer: Kyence, model: SI-F80R). Then, the polishing rate was calculated with the above Equation 2.

(3) Within-Wafer Non-Uniformity for a Tungsten Layer and an Oxide Layer

The silicon wafer having a tungsten layer and the silicon wafer having a silicon oxide (SiOx) layer prepared in the same manner as in the above Test Example (2) were each coated with 1 μm (10,000 Å) of a thermal oxide layer, which was polished for 1 minute under the conditions as described above. The in-plane film thickness at 98 points of the wafer was measured to calculate the within-wafer non-uniformity (WIWNU) by the following Equation 3:

Within-wafer non-uniformity (WIWNU)(%)=(standard deviation of polished thickness/average polished thickness)×100(%) [Equation 3]

TABLE 1

| Content (based on the composition for | | Example | | | | Comparative Example | | | |
|---|---|---|---|---|---|---|---|---|---|
| a polishing pad) | | 1 | 2 | 3 | 4 | 1 | 2 | 3 | 4 |
| Avg. particle diameter of the solid | | 33.8 | 35.1 | 27.4 | 40.0 | 60.8 | 25.3 | 24.3 | 25.3 |
| phase foaming agent (μm) | | | | | | | | | |
| Std. deviation of the avg. particle | | 9.86 | 8.95 | 9.13 | 10.15 | 10.6 | 10.6 | 11.5 | 10.6 |
| diameter of the solid phase foaming | | | | | | | | | |
| agent | | | | | | | | | |
| Introduced amount of the reaction rate | | 0.5 | 0.5 | 0.5 | 0.5 | 0.5 | 2.0 | 0.0 | 0.5 |
| controlling agent (part by weight) | | | | | | | | | |
| Introduced amount of the inert gas | | 10.0 | 15.0 | 15.0 | 15.0 | 15.0 | 5.0 | 30 | 25.0 |
| (% by volume) | | | | | | | | | |
| Introduced amount of the solid phase | | 1.5 | 1.5 | 1.5 | 1.5 | 1.5 | 2.5 | 0.5 | 0.5 |
| foaming agent (part by weight) | | | | | | | | | |
| Parameters on | Number average | 20.7 | 21.5 | 16.6 | 25.8 | 38.0 | 15.7 | 25.4 | 33.4 |
| pore | diameter of pores | | | | | | | | |
| distribution of | (Da) (μm) | | | | | | | | |
| the pad | Number median | 18.8 | 20.7 | 15.0 | 24.9 | 35.5 | 12.4 | 32.3 | 18.6 |
| | diameter of pores | | | | | | | | |
| | (Dm) (μm) | | | | | | | | |
| | Std. deviation | 11.0 | 8.62 | 8.83 | 10.35 | 4.58 | 10.21 | 17.6 | 18.21 |
| | (STDEV) | | | | | | | | |
| | Ed | 0.518 | 0.277 | 0.543 | 0.261 | 1.637 | 0.965 | −1.176 | 2.438 |
| Polishing | Polishing rate for a | 790 | 795 | 780 | 795 | 880 | 750 | 690 | 840 |
| characteristics | tungsten layer | | | | | | | | |
| of the pad | (Å/min) | | | | | | | | |
| | Within wafer | 4.2% | 2.9% | 3.5% | 3.6% | 5.5% | 4.3% | 11.5% | 5.0% |
| | non-uniformity for a | | | | | | | | |
| | tungsten layer (%) | | | | | | | | |
| | Polishing rate for an | 2931 | 2950 | 3050 | 2890 | 2734 | 3300 | 3530 | 3234 |
| | oxide layer (Å/min) | | | | | | | | |
| | Within-wafer | 3.7% | 3.8% | 3.5% | 3.7% | 4.8% | 4.9% | 10.5% | 8.2% |
| | non-uniformity for an | | | | | | | | |
| | oxide layer (%) | | | | | | | | |

As can be seen from Table 1, in Examples 1 to 4 in which the number average diameter (Da) of a plurality of pores was within the range of 16 μm to less than 30 μm and the Ed value was greater than 0, the polishing pads were remarkably excellent in the polishing rate and within-wafer non-uniformity for a tungsten layer and an oxide layer as compared with those of Comparative Examples 1 to 4.

Specifically, the polishing pads of Examples 1 to 4 had a polishing rate of 780 Å/min to 790 Å/min and 2,890 Å/min to 3,050 Å/min for a tungsten layer and an oxide layer, respectively. They also had an excellent within-wafer non-uniformity of 4.2% or less and 3.8 or less for a tungsten layer and an oxide layer, respectively.

In contrast, in Comparative Example 1 in which the number average diameter (Da) of a plurality of pores was 30 μm or more, the polishing pad had a polishing rate of 880 Å/min and a within-wafer non-uniformity of 5.5% for a tungsten layer, which were excessively high, and a polishing rate of 2,734 Å/min for an oxide layer, which was remarkably deteriorated as compared with the Examples.

Meanwhile, in Comparative Example 2 in which the number average diameter (Da) was less than 16 μm, the polishing pad had a polishing rate of 750 Å/min for a tungsten layer, which was very low, and a polishing rate of 3,300 Å/min for an oxide layer, which was excessively high.

In addition, in Comparative Example 2 in which the Ed value had a negative value of less than 0, the polishing pad had a polishing rate of 690 Å/min for a tungsten layer, which was remarkably low as compared with the Examples, and a within-wafer non-uniformity of 10% or more for both of a tungsten layer and an oxide layer, which were deteriorated by about two to four times as compared with Example 2.

In addition, in Comparative Example 4 in which the number average diameter (Da) of a plurality of pores was 30 μm or more and the Ed value was as high as 2 or more, the polishing pad had a polishing rate of 840 Å/min and a within-wafer non-uniformity of 5% for a tungsten layer, which were excessively high, and a polishing rate of 3,234 Å/min and a within-wafer non-uniformity of 8.2% for an oxide layer, showing that the polishing rate and within-wafer non-uniformity for both of a tungsten layer and an oxide layer were remarkably high as compared with the Examples.

[Reference Numeral of the Drawings]

| | |
|---|---|
| 110: polishing pad | 120: platen |
| 130: semiconductor substrate | 140: nozzle |
| 150: polishing slurry | 160: polishing head |
| 170: conditioner | |

1. A polishing pad, which comprises a polishing layer comprising a plurality of pores, wherein the plurality of pores have a number average diameter (Da) of 16 μm to less than 30 μm, and the Ed value represented by the following Equation 1 is greater than 0:
Ed=[3×(Da−Dm)]/STDEV [Equation 1]
in Equation 1, Da stands for the number average diameter of the plurality of pores within 1 mm² of the polishing surface, Dm stands for a number median diameter of the plurality of pores within 1 mm² of the polishing surface, and STDEV stands for a standard deviation of the number average diameter of the plurality of pores within 1 mm of the polishing surface.

2. The polishing pad of claim 1, wherein the Ed value represented by the above Equation 1 is greater than 0 to less than 2.

3. The polishing pad of claim 1, wherein the Dm is 12 μm to 28 μm, and the STDEV is 5 to 15.

4. The polishing pad of claim 1, wherein, in Equation 1, the Da is greater than the Dm by 0.3 μm to 3 μm.

5. The polishing pad of claim 1, wherein when, in Equation 1, the Da is 16 μm to less than 21 μm, the Ed value is greater than 0.5 to less than 2.

6. The polishing pad of claim 1, wherein when, in Equation 1, the Da is 21 μm to less than 30 μm, the Ed value is 0.1 to 0.5.

7. The polishing pad of claim 1, wherein the polishing layer comprises a cured material of a composition comprising a urethane-based prepolymer, a curing agent, and a solid phase foaming agent, and a content of the solid phase foaming agent is 0.7 parts by weight to 2 parts by weight based on 100 parts by weight of the composition.

8. The polishing pad of claim 7, wherein the solid phase foaming agent has an average particle diameter of 16 μm to 50 μm, and the standard deviation of the average particle diameter is 12 or less.

9. The polishing pad of claim 7, wherein the composition further comprises a reaction rate controlling agent in an amount of 0.05 parts by weight to 2 parts by weight based on 100 parts by weight of the composition, wherein the reaction rate controlling agent comprises at least one selected from a group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide.

10. The polishing pad of claim 1, which has a polishing rate of 700 Å/min to 900 Å/min for a tungsten layer.

11. The polishing pad of claim 1, which has a polishing rate of 2,750 Å/min to 3,200 Å/min for an oxide layer.

12. A process for preparing a polishing pad, which comprises:
mixing a composition comprising a urethane-based prepolymer, a curing agent, and a solid phase foaming agent, and
injecting the mixed composition into a mold under a reduced pressure to form a polishing layer,
wherein the polishing layer comprises a plurality of pores,
the plurality of pores have a number average diameter (Da) of 16 m to less than 30 μm, and
the Ed value represented by the following Equation 1 is greater than 0:
Ed=[3×(Da−Dm)]/STDEV [Equation 1]
in Equation 1, Da stands for the number average diameter of the plurality of pores within 1 mm² of the polishing surface, Dm stands for a number median diameter of the plurality of pores within 1 mm² of the polishing surface, and STDEV stands for a standard deviation of the number average diameter of the plurality of pores within 1 mm of the polishing surface.

13. The process for preparing a polishing pad of claim 12, wherein a gas phase foaming agent is introduced during the mixing in a volume of 6% to less than 25% based on the total volume of the composition.

14. A process for preparing a semiconductor device, which comprises:
mounting a polishing pad comprising a polishing layer comprising a plurality of pores on a platen; and
relatively rotating the polishing pad and a semiconductor substrate while a polishing surface of the polishing layer and a surface of the semiconductor substrate are in contact with each other to polish the surface of the semiconductor substrate,
wherein the plurality of pores have a number average diameter (Da) of 16 μm to less than 30 μm, and the Ed value represented by the following Equation 1 is greater than 0:
Ed=[3×(Da−Dm)]/STDEV [Equation 1]
in Equation 1, Da stands for the number average diameter of the plurality of pores within 1 mm² of the polishing surface, Dm stands for a number median diameter of the plurality of pores within 1 mm² of the polishing surface, and STDEV stands for a standard deviation of the number average diameter of the plurality of pores within 1 mm of the polishing surface.
